(19) United States
(12) Patent Application Publication
(10) Pub. No.: US 2026/0234006 A1
(43) Pub. Date: Aug. 13, 2026

(54) A METHOD FOR PREPARING DIAMOND ON THE BASIS OF GRAPHITE UNDER NORMAL PRESSURE

(71) Applicant: ZHEJIANG UNIVERSITY OF TECHNOLOGY, Hangzhou (CN)

(72) Inventors: Xiaojun HU, Hangzhou (CN); Zhiguang ZHU, Hangzhou (CN); Yudan WANG, Hangzhou (CN); Chengke CHEN, Hangzhou (CN); Shaohua LU, Hangzhou (CN); Xiao LI, Hangzhou (CN); Meiyan JIANG, Hangzhou (CN)

(21) Appl. No.: 18/866,991

(22) PCT Filed: Dec. 15, 2023
(86) PCT No.: PCT/CN2023/139135

§ 371 Date: Nov. 18, 2024

(30) Foreign Application Priority Data
Jan. 18, 2023 (CN) 202310059001.2

(51) Int. Cl. C01B 32/26; C01B 32/21

(52) U.S. Cl. CPC C01B 32/26; C01B 32/21; C01P 2004/03; C01P 2004/04

(57) ABSTRACT

A method for preparing diamond on the basis of graphite under normal pressure includes: depositing tantalum atoms, which escape from a tantalum wire during the heating thereof in an HFCVD system, on a graphite sheet, and converting graphite into diamond under normal pressure. The method has the advantages of low cost, energy conservation, environmental protection, etc.; and the method has low requirements for equipment, involves a simple process and is easy to operate.

### (1) FIELD OF THE INVENTION

The present invention relates to a novel method for preparing diamond on the basis of graphite under normal pressure.

### (2) BACKGROUND OF THE INVENTION

Diamond possesses extremely outstanding physicochemical properties, such as high hardness, high thermal conductivity, wide bandgap, and strong resistance to chemical corrosion, among others. It has extremely broad application prospects in fields such as industrial processing, electronic devices, and electrochemical electrodes. Especially as a typical representative of wide bandgap semiconductor materials, diamond is regarded as the most promising material for fabricating the next generation of high-power, high-frequency, high-temperature, and low-power-loss electronic devices, having significant impacts on future comprehensive national strength and national defense security.

Graphite, as a carbon material, is the most commonly used raw material for synthesizing diamond. Currently, the industrial methods for preparing diamond from graphite primarily include the high-temperature and high-pressure (HTHP) method and the explosive detonation method. The HTHP method fully mimics the natural mechanism of natural diamond growth underground, typically requiring pressures above 10 GPa and temperatures above 3000° C. to rearrange the carbon atoms in graphite into the structure of diamond. The individual diamond particles produced by this method are generally small in size. The explosive detonation method utilizes the instantaneous high-temperature and high-pressure environment generated by the explosion of high explosives to produce nanodiamond particles. This method yields a large quantity of nanodiamonds, but the diamond particles are small in size and mixed with the raw materials, making post-processing extremely difficult and the purification process very complex. The production conditions for both methods are extremely demanding, with phase transition pressures reaching several thousand MPa or even higher, temperature conditions reaching several thousand degrees Celsius, and high requirements for the equipment, and the production efficiency is low, the preparation cost is high, and the preparation difficulty is great. Researchers have also used the chemical vapor deposition (CVD) method to prepare diamond with graphite as a solid carbon source instead of gaseous carbon sources such as methane and acetone. However, this method requires high power and has a low diamond growth rate. Therefore, the development of new methods for synthesizing diamond from graphite holds significant value.

Previously, the inventors utilized an HFCVD system to deposit Ta atoms emitted from tantalum wires onto a graphite substrate, followed by vacuum annealing treatment to convert graphite into diamond under low pressure (see patent 202210305804.7). In that patent, the HFCVD system was used to treat the graphite substrate with Ta wires at powers of 2000 W and 2200 W, respectively. The selected Ta wire treatment powers were high and the treatment times were long, causing Ta atoms to react with the carbon in the graphite sheet to generate a large amount of TaC, which reduced the number of monodisperse Ta atoms and limited the phase transition from graphite to diamond. Therefore, in this patent, the inventors reduce the power and treatment time for Ta wire processing and optimize the annealing process to minimize the formation of TaC, obtain more monodisperse Ta atoms, and promote the graphite/diamond phase transition induced by monodisperse Ta atoms under normal pressure, thereby obtaining larger and more numerous diamonds.

### (3) BRIEF SUMMARY

The present invention provides a novel method for preparing diamond from graphite under normal pressure. This method utilizes an HFCVD (Hot Filament Chemical Vapor Deposition) system to deposit monodisperse tantalum atoms emitted from tantalum wires onto the surface of graphite at a relatively low power, followed by annealing treatment, thereby achieving the transformation of graphite into diamond under normal pressure.

To achieve the above objective, the present invention adopts the following technical solution:

The present invention provides a method for preparing diamond on the basis of graphite under normal pressure, comprising the following steps:
(1) pretreatment of graphite sheet: sequentially subjecting a graphite sheet (prepared by Beijing Electric Carbon Factory, with a purity of 99.9%) to grinding (using 2000-mesh and 4000-mesh abrasive papers successively), polishing (using polishing cloth), ultrasonically cleaning in an organic solvent, rinsing with deionized water, and drying (blown dry with a nitrogen gun) to obtain a pretreated graphite sheet; the purpose of the above pretreatment is to obtain a graphite sheet with smooth and clean surface;
(2) Ta wire treatment: placing the pretreated graphite sheet mentioned in step (1) in an HFCVD (Hot Filament Chemical Vapor Deposition) device as a substrate for tantalum deposition (without the need for a carbon source; it is not a chemical vapor deposition process but uses the Ta wire in the equipment as both the heat source and tantalum source), positioning the pretreated graphite sheet directly below the tantalum wire, adjusting the hydrogen flow rate to 10~350 sccm (preferably 100 sccm), controlling the power at 300~800 W (preferably 400 W) and the pressure at 3~5 kPa (preferably 3.5 kPa), and carrying out the treatment for 1~60 minutes (preferably 5 min to 15 min, more preferably 15 min); afterward, reducing the power to 0 at a rate of 1 V/min in a hydrogen atmosphere to obtain a tantalum-treated graphite sheet;
(3) annealing treatment: sealing the tantalum-treated graphite sheet mentioned in step (2) in a quartz tube and placing the quartz tube in a muffle furnace for annealing at a temperature of 400~1300° C. for 10~180 minutes (preferably annealing at 500~1200° C. for 30~120 minutes, further preferably annealing at 1100° C. for 120 minutes) to obtain diamond.

Furthermore, the graphite sheet mentioned in step (1) is a polycrystalline graphite sheet with a size of 10×10×2 mm and a purity of 99.9%.

Furthermore, the organic solvent mentioned in step (1) is ethanol or acetone, preferably ethanol.

In the embodiment of the present invention for step (1), the equipment for ultrasonically cleaning is manufactured by Kunshan Ultrasonic Instrument Co., Ltd., with a model number of KQ5200DE, the conditions for are 100 W-200 W, preferably 140 W ultrasonically cleaning for 15 minutes.

Preferably, the hot filament chemical vapor deposition equipment mentioned in step (2) is purchased from Shanghai JiaoYou Diamond Coating Company, with a model number of JUHFCVD001.

Compared with the existing process of converting graphite into diamond under high temperature and high pressure, the beneficial effects of the present invention are as follows: (1) By depositing tantalum atoms emitted from the tantalum wire heated in the HFCVD system onto the graphite sheet, the transformation of graphite into diamond is achieved under normal pressure, offering advantages such as low cost, energy conservation, and environmental protection; (2) This method has relatively low requirements on the equipment, involves a simple process, and is easy to operate; (3) Compared with the inventor's previous process of converting graphite into diamond under low pressure (see patent 202210305804.7), the process of the present invention is simpler, has a shorter cycle, and obtains a larger quantity and larger size of diamonds, providing a more feasible scheme for preparing diamond based on the phase transformation of graphite under normal pressure.

### (4) BRIEF DESCRIPTION OF DRAWINGS

FIG. 1 is a Scanning Electron Microscope (SEM) image of the intrinsic graphite substrate after pretreatment.

FIG. 2 is a Transmission Electron Microscope (TEM) image of the intrinsic graphite substrate after pretreatment.

FIG. 3 is an SEM image of Example 1 (400 W—tantalum wire treatment for 15 min—annealing at 500° C.—30 min).

FIG. 4 is a TEM image of Example 1 (400 W—15 min—500° C.—30 min).

FIG. 5 is an SEM image of Example 2 (400 W—15 min—1100° C.—30 min).

FIG. 6 is a TEM image of Example 2 (400 W—15 min—1100° C.—30 min).

FIG. 7 is an SEM image of Example 3 (400 W—15 min—1100° C.—120 min).

FIG. 8 is a TEM image of Example 3 (400 W—15 min—1100° C.—120 min).

FIG. 9 is an SEM image of Example 4 (400 W—15 min—1200° C.—30 min).

FIG. 10 is a TEM image of Example 4 (400 W—15 min—1200° C.—30 min).

FIG. 11 is an SEM image of Example 5 (400 W—5 min—1100° C.—30 min).

FIG. 12 is a TEM image of Example 5 (400 W—5 min—1100° C.—30 min).

### (5) DETAILED DISCLOSURE

The following are further explanations of the present invention through specific examples, but the scope of protection of the present invention is not limited to these.

### EXAMPLE 1

(1) A graphite sheet (prepared by Beijing Electric Carbon Factory, with a purity of 99.9%) was ground (initially with 2000-mesh sandpaper and then with 4000-mesh sandpaper), polished (using polishing cloth), and ultrasonically cleaned in ethanol (manufactured by Kunshan Ultrasonic Instrument Co., Ltd., model KQ5200DE, 140 W for 15 minutes). After cleaning with deionized water, it was dried (blown dry with a nitrogen gun) to obtain a pretreated graphite sheet. The purpose of the above pretreatment was to obtain a graphite sheet with smooth and clean surface.
(2) The tantalum wire was installed in a double helix configuration. The pretreated graphite sheet from step (1) was placed in a Hot Filament Chemical Vapor Deposition (HFCVD) device, hydrogen was introduced at a flow rate of 100 sccm, the power was controlled at 400 W, and the pressure was stabilized at 3.5 kPa. After 15 minutes of processing, the power was reduced to 0 at a rate of 1 V/min in the hydrogen atmosphere to complete the Ta deposition treatment.
(3) The treated graphite sheet from step (2) was placed inside a quartz tube for sealing, and the sealed quartz tube (containing the sample) was placed in a muffle furnace at 500° C. After annealing for 30 minutes, the sample was removed to complete the annealing process.

The composition of the post-experiment sample was observed using Field Emission Scanning Electron Microscopy (FESEM) and High-Resolution Transmission Electron Microscopy (HRTEM).

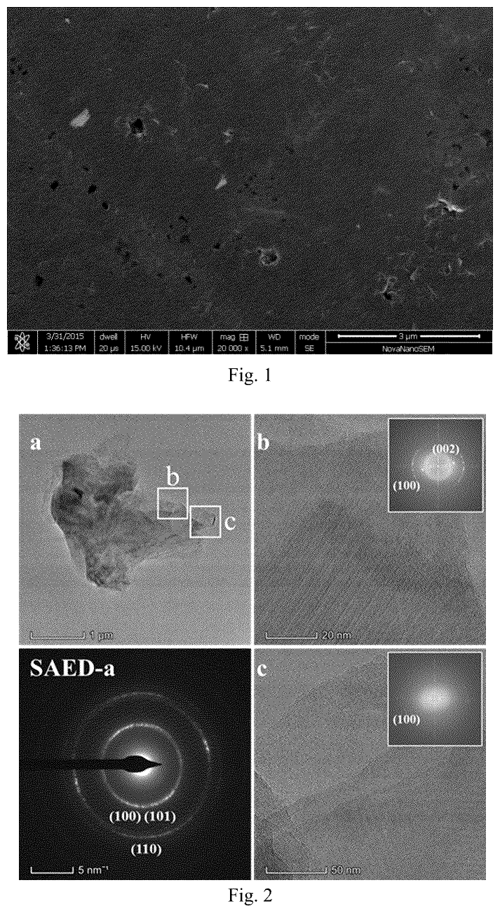

FIG. 1 shows the SEM image of the intrinsic graphite substrate after pretreatment, with a very smooth graphite surface.

FIG. 2 shows the TEM image of the intrinsic graphite substrate after pretreatment, mainly displaying crystallographic plane information such as (002) and (100) of graphite.

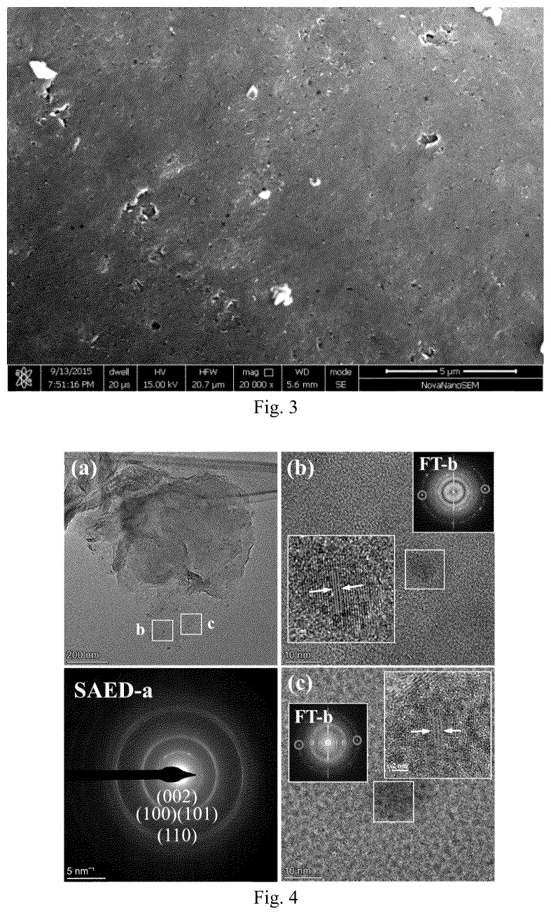

FIG. 3 shows the SEM image of the sample of Example 1, with a few nanoparticles present on the sample surface after annealing treatment.

FIG. 4 shows the TEM image of the sample of Example 1. From the low-magnification image, a small number of black nanoparticles can be seen on the thin area of the sample. SAED-a mainly shows diffraction rings of the (002), (100), (101), and (110) crystallographic planes of graphite. Figure (b) displays a high-magnification image of the nanoparticles, in which there is a granular-sized region with clear lattice stripes inside the particle with an interplanar spacing of 0.210 nm, corresponding to the (111) plane of cubic diamond. The magnified image (c) of particle c shows lattice stripes with an interplanar spacing of 0.212 nm within the particle, close to the interplanar spacing of the (111) plane of cubic diamond. Outside the particle, lattice stripes of the (002) plane of graphite are also present. The previous analysis indicates the presence of nanodiamond particles with sizes around 8-12 nm in the sample.

### EXAMPLE 2

(1) A graphite sheet (prepared by Beijing Electric Carbon Factory, with a purity of 99.9%) was ground (initially with 2000-mesh sandpaper and then with 4000-mesh sandpaper), polished (using polishing cloth), and ultrasonically cleaned in ethanol (manufactured by Kunshan Ultrasonic Instrument Co., Ltd., model KQ5200DE, 140 W for 15 minutes). After cleaning with deionized water, it was dried (blown dry with a nitrogen gun) to obtain a pretreated graphite sheet. The purpose of the above pretreatment was to obtain a graphite sheet with smooth and clean surface.
(2) The tantalum wire was installed in a double helix configuration. The pretreated graphite sheet from step (1) was placed in a Hot Filament Chemical Vapor Deposition (HFCVD) device, hydrogen was introduced at a flow rate of 100 sccm, the power was controlled at 400 W, and the pressure was stabilized at 3.5 kPa. After 15 minutes of processing, the power was reduced to 0 at a rate of 1 V/min in a hydrogen atmosphere to complete the Ta deposition treatment.
(3) The treated graphite sheet from step (2) was placed inside a quartz tube for sealing, and the sealed quartz tube (containing the sample) was placed in a muffle furnace at 1100° C. After annealing for 30 minutes, the sample was removed to complete the annealing process.

The composition of the post-experiment sample was observed using Field Emission Scanning Electron Microscopy (FESEM) and High-Resolution Transmission Electron Microscopy (HRTEM).

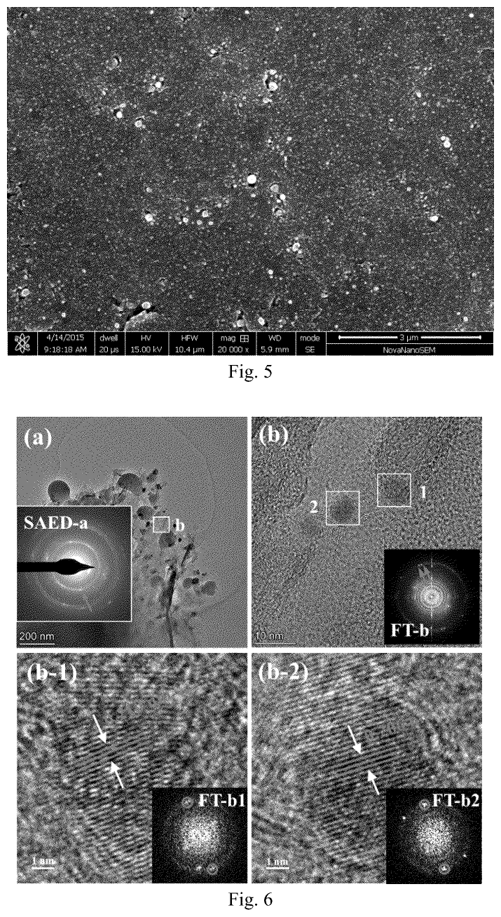

FIG. 5 shows the SEM image of the sample of Example 2. After annealing treatment, many spherical nanoparticles were generated on the sample surface. Compared to the sample annealed at 500° C. (Example 1), the number of nanoparticles on the surface increased significantly, and their sizes became larger.

FIG. 6 shows the TEM image of the sample of Example 2. From the low-magnification image, more nanospherical particles can be seen on the thin area of the sample. SAED-a mainly shows diffraction rings of the (002), (100), and (101) crystallographic planes of graphite. Figure (b) displays a high-magnification image of the nanoparticles, with FT-b showing two pairs of diffraction spots corresponding to the positions of the two particles in Figure (b). The magnified image b-1 of particle 1 reveals clear lattice stripes within the particle, with an interplanar spacing of 0.210 nm, corresponding to the (111) plane of cubic diamond. The magnified image of particle 2 also shows lattice stripes with an interplanar spacing of 0.206 nm within the particle, consistent with the interplanar spacing of the (111) plane of cubic diamond. It can be concluded that diamond nanoparticles with sizes of about 5 nm are present in the sample.

### EXAMPLE 3

(1) A graphite sheet (prepared by Beijing Electric Carbon Factory, with a purity of 99.9%) was ground (initially with 2000-mesh sandpaper and then with 4000-mesh sandpaper), polished (using polishing cloth), and ultrasonically cleaned in ethanol (manufactured by Kunshan Ultrasonic Instrument Co., Ltd., model KQ5200DE, 140 W for 15 minutes). After cleaning with deionized water, it was dried (blown dry with a nitrogen gun) to obtain a pretreated graphite sheet. The purpose of the above pretreatment was to obtain a graphite sheet with smooth and clean surface.
(2) The tantalum wire was installed in a double helix configuration. The pretreated graphite sheet from step (1) was placed in a Hot Filament Chemical Vapor Deposition (HFCVD) device, and hydrogen was introduced at a flow rate of 100 sccm, the power was controlled at 400 W, and the pressure was stabilized at 3.5 kPa. After 15 minutes of processing, the power was reduced to 0 at a rate of 1 V/min in a hydrogen atmosphere to complete the Ta deposition treatment.
(3) The treated graphite sheet from step (2) was placed inside a quartz tube for sealing, and the sealed quartz tube (containing the sample) was placed in a muffle furnace at 1100° C. After annealing for 120 minutes, the sample was removed to complete the annealing process.

The composition of the post-experiment sample was observed using Field Emission Scanning Electron Microscopy (FESEM) and High-Resolution Transmission Electron Microscopy (HRTEM).

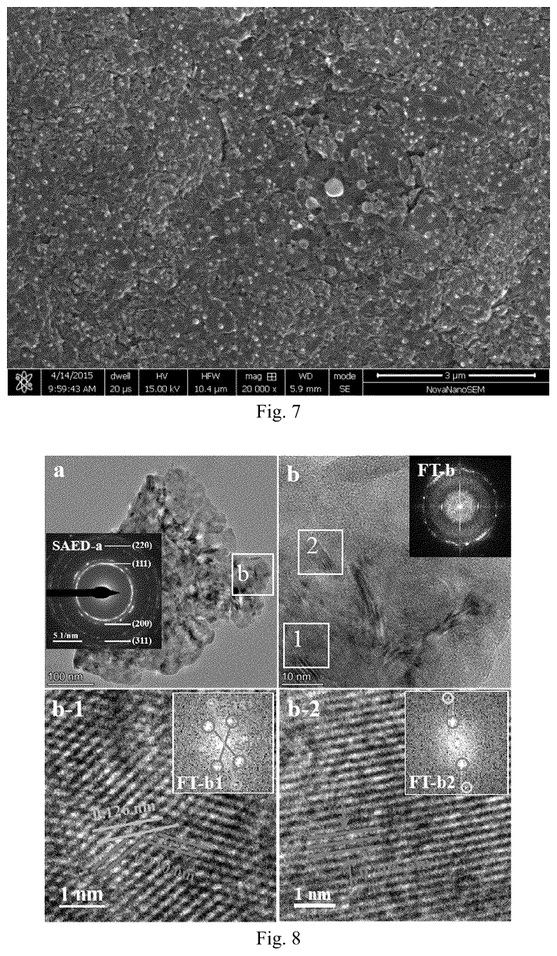

FIG. 7 shows the SEM image of the sample of Example 3. After annealing treatment, spherical nanoparticles were present on the sample surface. Compared to the sample annealed for 30 minutes (Example 2), the number of particles on the surface was higher, and their sizes were larger.

FIG. 8 shows the TEM image of the sample of Example 3. SAED-a displays diffraction rings corresponding to the (111), (200), (220), and (311) crystallographic planes of diamond. Figure (b) is a magnified view of region b in Figure (a), and the corresponding FT image FT-b shows diffraction information for crystallographic planes with an interplanar spacing of 0.210 nm. The FT image FT-b1 of region 1 in Figure (b) displays diffraction information for crystallographic planes with interplanar spacings of 0.210 nm and 0.126 nm, corresponding to the (111) and (220) planes of diamond, respectively. The angles between the (111) and (111) planes, and between the (111) and (220) planes, are 70° and 35°, respectively, which are consistent with the standard angles of crystallographic plane intersections. In Figure b-1, corresponding lattice stripes with spacings of 0.210 nm and 0.126 nm are present. The FT image FT-b2 of region 2 displays diffraction information for crystallographic planes with spacings of 0.206 nm and 0.104 nm, corresponding to the (111) and (222) planes of diamond. In the magnified view b-2, corresponding lattice stripes with a spacing of 0.206 nm, belonging to the (111) crystallographic plane of diamond, are present. Analysis reveals that a relatively large amount of diamond was obtained in this region, with sizes ranging from 10 nm to 15 nm.

### EXAMPLE 4

(1) A graphite sheet (prepared by Beijing Electric Carbon Factory, with a purity of 99.9%) was ground (initially with 2000-mesh sandpaper and then with 4000-mesh sandpaper), polished (using polishing cloth), and ultrasonically cleaned in ethanol (manufactured by Kunshan Ultrasonic Instrument Co., Ltd., model KQ5200DE, 140 W for 15 minutes). After cleaning with deionized water, it was dried (blown dry with a nitrogen gun) to obtain a pretreated graphite sheet. The purpose of the above pretreatment was to obtain a graphite sheet with smooth and clean surface.
(2) The tantalum wire was installed in a double helix configuration. The pretreated graphite sheet from step (1) was placed in a Hot Filament Chemical Vapor Deposition (HFCVD) device, and hydrogen was introduced at a flow rate of 100 sccm, the power was controlled at 400 W, and the pressure was stabilized at 3.5 kPa. After 15 minutes of processing, the power was reduced to 0 at a rate of 1 V/min in a hydrogen atmosphere to complete the Ta deposition treatment.
(3) The treated graphite sheet from step (2) was placed inside a quartz tube for sealing, and the sealed quartz tube (containing the sample) was placed in a muffle furnace at 1200° C. After annealing for 30 minutes, the sample was removed to complete the annealing process.

The composition of the post-experiment samples was observed using Field Emission Scanning Electron Microscopy (FESEM) and High-Resolution Transmission Electron Microscopy (HRTEM).

FIG. 9 shows the SEM image of the sample of Example 4. After annealing treatment, the sample surface exhibited a dense distribution of spherical nanoparticles. Compared to the sample annealed at 1100° C. (Example 2), the number of nanoparticles on the surface was higher, and their sizes were larger.

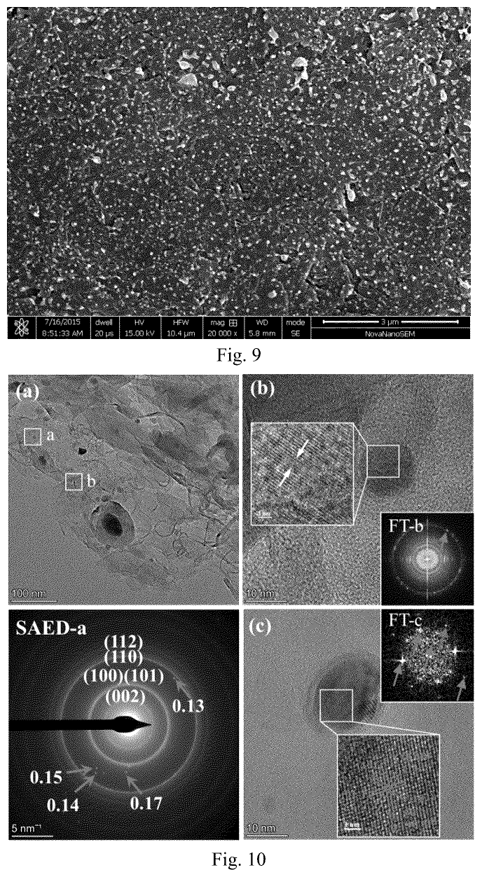

FIG. 10 shows the TEM image of the sample of Example 4. The low-magnification TEM image (a) reveals the presence of numerous black particles in the sample. SAED-a mainly displays diffraction rings corresponding to graphite (002), (100), (101), (110), and (112), with additional diffraction spots corresponding to interplanar spacings of 0.170 nm, 0.150 nm, 0.140 nm, and 0.130 nm. Figure (c) is a magnified view of region b in Figure (a), and the FT-b image displays a diffraction ring with an interplanar spacing of 0.210 nm. The diffraction spot regions corresponding to the arrows coincide with the particle positions in Figure (b). From the magnified image of the particles, it can be seen that the particles have clear lattice stripes with an interplanar spacing of 0.210 nm, which corresponds to the (111) plane of cubic diamond. The FT image of Figure (c) displays diffraction information for interplanar spacings of 0.190 nm, 0.150 nm, and 0.130 nm, which are close to the (101), (102), and (110) planes of hexagonal diamond. By measuring the angles between the crystallographic planes, it is found that they are consistent with the standard crystallographic plane angles of the hexagonal diamond structure. The previous analysis indicates that diamonds with sizes greater than 10 nm are obtained in the sample.

### EXAMPLE 5

(1) A graphite sheet (prepared by Beijing Electric Carbon Factory, with a purity of 99.9%) was ground (initially with 2000-mesh sandpaper and then with 4000-mesh sandpaper), polished (using polishing cloth), and ultrasonically cleaned in ethanol (manufactured by Kunshan Ultrasonic Instrument Co., Ltd., model KQ5200DE, 140 W for 15 minutes). After cleaning with deionized water, it was dried (blown dry with a nitrogen gun) to obtain a pretreated graphite sheet. The purpose of the above pretreatment was to obtain a graphite sheet with smooth and clean surface.
(2) The tantalum wire was installed in a double helix configuration. The pretreated graphite sheet from step (1) was placed in a Hot Filament Chemical Vapor Deposition (HFCVD) device, and hydrogen was introduced at a flow rate of 100 sccm, the power was controlled at 400 W, and the pressure was stabilized at 3.5 kPa. After 5 minutes of processing, the power was reduced to 0 at a rate of 1 V/min in a hydrogen atmosphere to complete the Ta deposition treatment.
(3) The treated graphite sheet from step (2) was placed inside a quartz tube for sealing, and the sealed quartz tube (containing the sample) was placed in a muffle furnace at 1100° C. After annealing for 30 minutes, the sample was removed to complete the annealing process.

The composition of the post-experiment sample was observed using Field Emission Scanning Electron Microscopy (FESEM) and High-Resolution Transmission Electron Microscopy (HRTEM).

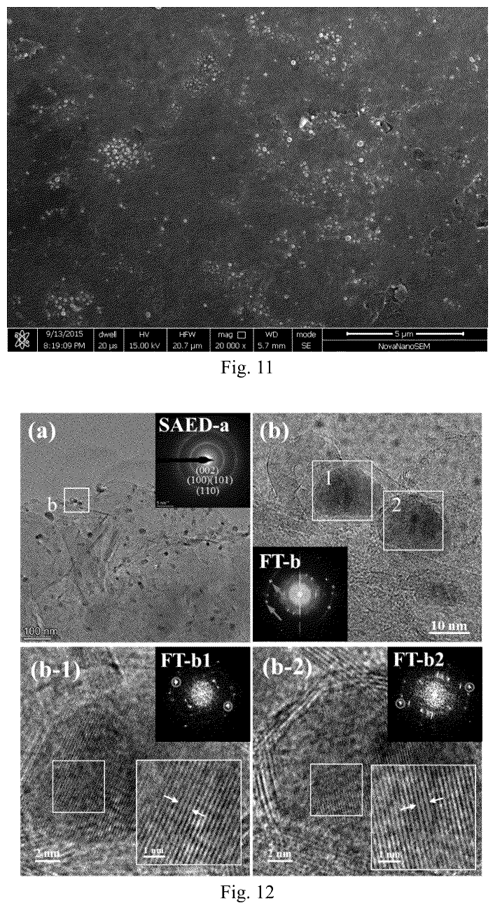

FIG. 11 shows the SEM image of the sample of Example 5. After annealing treatment, a small number of spherical nanoparticles are present on the sample surface. Compared to the sample with Ta wire treatment for 15 minutes (Example 2), the number of nanoparticles on the surface is significantly reduced, and the particle sizes are more uniform.

FIG. 12 shows the TEM image of the sample of Example 5. From the low-magnification image, it can be seen that there are many small black nanoparticles on the thin area of the sample. SAED-a mainly displays diffraction rings corresponding to the (002), (100), and (101) planes of graphite. Figure (b) shows a high-magnification image of the nanoparticles, and FT-b has two pairs of diffraction spots corresponding to the positions of the two particles in Figure (b). The magnified image b-1 of particle 1 reveals clear lattice stripes inside the particle with an interplanar spacing of 0.212 nm, which is close to the (111) plane of cubic diamond. The magnified image b-2 of particle 2 also shows lattice stripes inside the particle with a spacing of 0.202 nm, which is consistent with the crystallographic plane spacing of the (111) plane of cubic diamond. Both particles are surrounded by lattice stripes corresponding to the (002) plane of graphite on their outer surfaces. The previous analysis indicates that there are nanodiamond particles with sizes around 10 nm present in the sample.

1. A method for preparing diamond on the basis of graphite under normal pressure, comprising the following steps:
(1) pretreatment of graphite sheet: sequentially subjecting a graphite sheet to grinding, polishing, ultrasonically cleaning in an organic solvent, rinsing with deionized water, and drying to obtain a pretreated graphite sheet;
(2) Ta wire treatment: placing the pretreated graphite sheet mentioned in step (1) in a Hot Filament Chemical Vapor Deposition device as a substrate for tantalum deposition, positioning the pretreated graphite sheet directly below a tantalum wire, adjusting the hydrogen flow rate to 10~350 sccm, controlling the power at 300~800 W and the pressure at 3~5 kPa, and carrying out the treatment for 1~60 minutes; afterward, reducing the power to 0 at a rate of 1 V/min in the hydrogen atmosphere to obtain a tantalum-treated graphite sheet;
(3) annealing treatment: sealing the tantalum-treated graphite sheet mentioned in step (2) in a quartz tube and placing the quartz tube in a muffle furnace for annealing at a temperature of 400~1300° C. for 10~180 minutes to obtain diamond.

2. The method for preparing diamond on the basis of graphite under normal pressure of claim 1, wherein the graphite sheet mentioned in step (1) is a polycrystalline graphite sheet with a size of 10×10×2 mm and a purity of 99.9%. Furthermore,

3. The method for preparing diamond on the basis of graphite under normal pressure of claim 1, wherein the organic solvent mentioned in step (1) is ethanol or acetone.

4. The method for preparing diamond on the basis of graphite under normal pressure of claim 3, wherein the organic solvent mentioned in step (1) is ethanol.

5. The method for preparing diamond on the basis of graphite under normal pressure of claim 1, wherein the hydrogen flow rate is 100 sccm.

6. The method for preparing diamond on the basis of graphite under normal pressure of claim 1, wherein the power is controlled at 400 W.

7. The method for preparing diamond on the basis of graphite under normal pressure of claim 1, wherein the pressure is controlled at 3.5 kPa.

8. The method for preparing diamond on the basis of graphite under normal pressure of claim 1, wherein the treatment time in step (2) is 5 min~15 min.

9. The method for preparing diamond on the basis of graphite under normal pressure of claim 1, wherein the annealing in step (3) is carried out at a temperature of 500~1200° C. for 30~120 min.

10. The method for preparing diamond on the basis of graphite under normal pressure of claim 9, wherein the annealing in step (3) is carried out at a temperature of 1100° C. for 120 min.
